(19) United States
(12) Patent Application Publication
(10) Pub. No.: US 2024/0364337 A1
(43) Pub. Date: Oct. 31, 2024

(54) EXCESSIVE CURRENT PROTECTION FOR BOOTSTRAP CAPACITOR CHARGING

(71) Applicant: TEXAS INSTRUMENTS INCORPORATED, Dallas, TX (US)

(72) Inventors: Weibing Jing, Beijing (CN); Dan Li, Beijing (CN)

(21) Appl. No.: 18/308,100

(22) Filed: Apr. 27, 2023

(51) Int. Cl. H03K 19/017; H03K 17/06; H03K 17/081

(52) U.S. Cl. CPC H03K 19/01714; H03K 17/063; H03K 17/08104

(57) ABSTRACT

According to some aspects, a circuit, such as an integrated circuit, comprises a bootstrap capacitor terminal, a bootstrap capacitor charging circuit coupled to the bootstrap capacitor terminal; and a bootstrap capacitor charging current limiting circuit coupled to the bootstrap capacitor charging circuit. According to some aspects, the circuit comprises a capacitor terminal, a capacitor charging transistor coupled to the capacitor terminal, a capacitor charging current sensing transistor coupled to the capacitor charging transistor, a current programming transistor coupled to the capacitor charging current sensing transistor; and a capacitor current limiting transistor coupled to the capacitor charging current sensing transistor, to the current programming transistor, and to the capacitor charging transistor. According to some aspects, an apparatus comprises a memory storing instructions to cause a processor to instantiate bootstrap capacitor charging current limiting circuit features.

### BACKGROUND

Direct current (DC) to DC converters can be used to perform various functions in electronics circuits such as voltage stepping up/down, voltage regulation, etc. Typically, DC-to-DC converters include one or more switches, and a pulse width modulation (PWM) signal may be used to control operation of the one or more switches to control the switching frequency. The switching frequency and input voltage of the DC-to-DC converter affect an output voltage of the DC to DC converter. The one or more switches may include a high-side transistor, and a bootstrap circuit is often provided to assure reliable operation of the high-side transistor.

### SUMMARY

According to some aspects, a circuit, such as an integrated circuit, comprises a bootstrap capacitor terminal, a bootstrap capacitor charging circuit coupled to the bootstrap capacitor terminal; and a bootstrap capacitor charging current limiting circuit coupled to the bootstrap capacitor charging circuit. According to some aspects, the circuit comprises a capacitor terminal, a capacitor charging transistor coupled to the capacitor terminal, a capacitor charging current sensing transistor coupled to the capacitor charging transistor, a current programming transistor coupled to the capacitor charging current sensing transistor; and a capacitor current limiting transistor coupled to the capacitor charging current sensing transistor, to the current programming transistor, and to the capacitor charging transistor. According to some aspects, an apparatus comprises a memory storing instructions to cause a processor to instantiate bootstrap capacitor charging current limiting circuit features.

### BRIEF DESCRIPTION OF THE DRAWINGS

FIG. 1 is a block diagram illustrating a circuit with a current-limited bootstrap charging circuit comprising a current limiting circuit and bootstrap capacitor charging circuit in accordance with some aspects of the present disclosure.

FIG. 2 is a block diagram illustrating a circuit with a high-side control circuit and a bootstrap capacitor charge control circuit in accordance with some aspects of the present disclosure.

FIG. 3 is a schematic diagram illustrating a high-side control circuit in accordance with some aspects of the present disclosure.

FIG. 4 is a block diagram illustrating a system comprising a DC-to-DC converter comprising a current limiting circuit in accordance with some aspects of the present disclosure.

FIG. 5 is a graph showing voltage vs. time and current vs. time for an unprotected bootstrap charging circuit and for a current-limited bootstrap charging circuit in accordance with some aspects of the present disclosure.

FIG. 6 is a state diagram illustrating states in which a current-limited bootstrap charging circuit can operate in accordance with some aspects of the present disclosure.

FIG. 7 and FIG. 8 are a flow diagram illustrating a method by which a current-limited bootstrap charging circuit may operate in accordance with some aspects of the present disclosure.

FIG. 9 is a flow diagram illustrating a method by which a current-limited bootstrap charging circuit may operate in accordance with some aspects of the present disclosure.

FIG. 10 is a block diagram illustrating apparatus comprising a processor and memory, the memory storing instructions executable by the processor in accordance with some aspects of the present disclosure.

FIG. 11 is a flow diagram illustrating a method by which a current-limited bootstrap charging circuit may operate in accordance with some aspects of the present disclosure

### DETAILED DESCRIPTION

The drawings are not drawn to scale.

DC-to-DC converters are utilized in a wide variety of electronic circuits due to their ability to step up/down and regulate DC voltages. DC-to-DC converter may comprise a voltage input, an inductor, a capacitor, and one or more switches. During operation, the one or more switches are opened and closed at a high frequency; the operation of the one or more switches is used to control current paths within the converter and through the inductor. An output voltage is generated based on a switching frequency and a topology of the DC-to-DC converter. DC-to-DC converters may come in a variety of topologies that provide a variety of relationships between the voltage of the input and the output, where the placement of the voltage input, inductor, capacitor, and one or more switches varies based on the topology.

A DC-to-DC converter may comprise a bootstrap (BOOT) capacitor, which can be charged, by a bootstrap capacitor charging (BOOT CHARGE) circuit, to a bootstrap capacitor voltage above a high-side transistor gate voltage sufficient to turn on the high-side transistor. In some cases, the voltage to turn on the high-side transistor may be higher than the input voltage of the converter. The bootstrap capacitor may be provided external to an integrated circuit package of the converter, where phenomena outside the control of the manufacturer of the integrated circuit can occur. For example, if no protection were provided and if an unintentional low-impedance path from a terminal of the bootstrap capacitor to another voltage (e.g., a short circuit to ground) were to occur, a large amount of current could flow through the bootstrap capacitor charging circuit, causing unacceptably high power dissipation in the integrated circuit package.

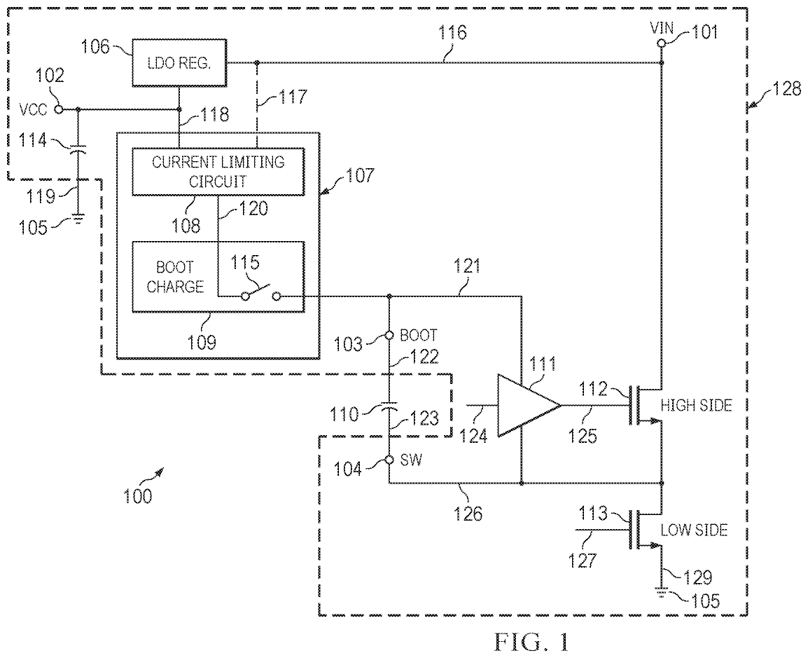

FIG. 1 is a block diagram illustrating a circuit with a current-limited bootstrap charging circuit comprising a current limiting circuit and bootstrap capacitor charging circuit in accordance with some aspects of the present disclosure. Circuit 100 comprises input voltage (VIN) terminal 101, regulated voltage (VCC) terminal 102, bootstrap capacitor terminal 103, switched (SW) terminal 104, ground terminal 105, voltage regulator (e.g., low dropout (LDO) regulator (REG)) 106, current-limited bootstrap charging circuit 107, bootstrap capacitor 110, driver 111, high-side transistor 112, low-side transistor 113, and capacitor 114. Current-limited bootstrap charging circuit 107 comprises current limiting circuit 108 and bootstrap capacitor charging circuit 109. Bootstrap capacitor charging circuit comprises a switch 115. Input voltage terminal 101 is coupled to input voltage connection structure 116. Input voltage connection structure 116 is coupled to an input terminal of voltage regulator 106. An output terminal of voltage regulator 106 is coupled to regulated voltage connection structure 118, which is coupled to regulated voltage terminal 102, to a first terminal of capacitor 114, and to an input of current limiting circuit 108. Alternatively or in addition to the connection of regulated voltage connection structure 118 to the input of current limiting circuit 108, a connection structure 117 can connect input voltage connection structure 116 to an input of current limiting circuit 108. Current limiting circuit 108 can be supplied with a supply voltage from any of a number of sources, such as input voltage terminal 101, regulated voltage terminal 102, both, or the like. Thus, a supply voltage at a supply voltage terminal may be the input voltage at input voltage terminal 101, a regulated voltage at regulated voltage terminal 102, or a different supply voltage at a different supply voltage terminal. A second terminal of capacitor 114 is coupled to ground connection structure 119, which is coupled to ground terminal 105.

An output of current limiting circuit 108 is coupled to an input of bootstrap capacitor charging circuit 109 via bootstrap capacitor charging connection structure 120, which is coupled to a first terminal of switch 115. A second terminal of switch 115 is coupled to bootstrap capacitor connection structure 121, which is coupled to bootstrap capacitor terminal 103 and to a first driver supply voltage terminal of driver 111. Bootstrap capacitor terminal 103 is coupled to a first terminal 122 of bootstrap capacitor 110. A second terminal 123 of bootstrap capacitor 110 is coupled to switched terminal 104. Switched terminal 104 is coupled to switched connection structure 126, which is coupled to a second driver supply voltage terminal of driver 111, to a source terminal of high-side transistor 112, and to a drain terminal of low-side transistor 113.

Input terminal 124 of driver 111 receives an input high-side control signal. Driver 111 provides an output high-side control signal at connection structure 125, which is coupled to a gate terminal of high-side transistor 112. An output low-side control signal at connection structure 127 is provided to a gate terminal of low-side transistor 113. A source terminal of low-side transistor 113 is coupled to ground connection structure 129, which is coupled to ground terminal 105. A drain terminal of high-side transistor 112 is coupled to input voltage connection structure 116. In some examples, the elements of circuit 100 illustrated as falling within the polygon 128 are disposed on a single integrated circuit or “chip,” while other components, such as the bootstrap capacitor 110 and capacitor 114, can be external to the chip. Thus, these elements within polygon 128 can be disposed on a single monocrystalline silicon substrate, and/or can be disposed in a so-called three dimensional integrated circuit where multiple silicon substrates are stacked over one another in a circuit package. In other examples, the elements within polygon 128 can be assembled by using discrete components, but integrating them into one chip can offer easier integration and setup in many regards.

Bootstrap capacitor charging circuit 109 can be used to charge bootstrap capacitor 110 to a bootstrap capacitor voltage high enough to reliably drive high-side transistor 112. For example, sufficient bootstrap capacitor voltage can reliably power driver 111 to drive high-side transistor 112. As an example, high-side transistor 112 can be a N-channel field-effect transistor (NFET), for which the gate terminal is raised to a voltage higher than the source terminal to turn on the NFET. Since high-side transistor 112 has its drain terminal coupled to input voltage connection structure 116, turning on high-side transistor 112 will raise its source terminal to nearly the input voltage of the input voltage connection structure 116, potentially requiring a voltage higher than the input voltage to be applied to the gate terminal of high-side transistor 112 to keep it reliably turned on.

Low-side transistor 113 can also be a NFET but its gate terminal can readily be raised to a voltage higher than its source terminal, as its source terminal is at ground voltage. When low-side transistor 113 is on, closure of switch 115 can charge the bootstrap capacitor to nearly the supply voltage (e.g., the regulated voltage (VCC) or the input voltage (VIN)). Then, by turning off switch 115 and low-side transistor 113, the charged voltage of the bootstrap capacitor can reliably turn on high-side transistor 112 even as the conduction of high-side transistor 112 turning on raises the voltage of connection structure 126, as that rising voltage will push the voltage of bootstrap capacitor connection structure 121 upward, even to a voltage above VCC. With switch 115 open, bootstrap capacitor 110 can maintain its charged voltage, which provides the difference between the voltage of bootstrap capacitor connection structure 121 and the voltage of connection structure 126. When the turning on of high-side transistor 112 raises the voltage of connection structure 126 to nearly the supply voltage (e.g., nearly the voltage of input voltage connection structure 116), the voltage at bootstrap capacitor connection structure 121 can then rise to nearly the sum of the supply voltage and the bootstrap capacitor voltage across bootstrap capacitor 110, providing a voltage at bootstrap capacitor connection structure 121 sufficient to drive (directly or via driver 111) the gate terminal of high-side transistor 112 with a gate terminal voltage sufficiently above the source terminal voltage of high-side transistor 112 to reliably turn on high-side transistor 112.

In accordance with some aspects, the switch 115 of the bootstrap capacitor charging circuit 109 can be in a closed position to provide normal operation for the charging of a capacitor, such as bootstrap capacitor 110, at typically moderate current and power dissipation levels when no faults exist. However, in the event of a fault, such as an inadvertent connection of part of the circuit, for example, the bootstrap capacitor terminal 103, to some point that electrically completes an undesired circuit, for example, a short circuit to a different voltage, such as ground; the switch 115 remains in the closed position but the current limiting circuit 108 can limit the current through the switch 115 to mitigate current and power excursions from nominal values. Thus, an integrated circuit incorporating features as described herein can improve reliability and safety even for faults that may occur elsewhere in a system in which the integrated circuit is used. While providing current limiting if and when needed, a circuit as described herein can remain inactive in the vast majority of instances over the vast majority of times when no fault typically occurs. Therefore, performance and efficiency can be maintained while protection can be provided.

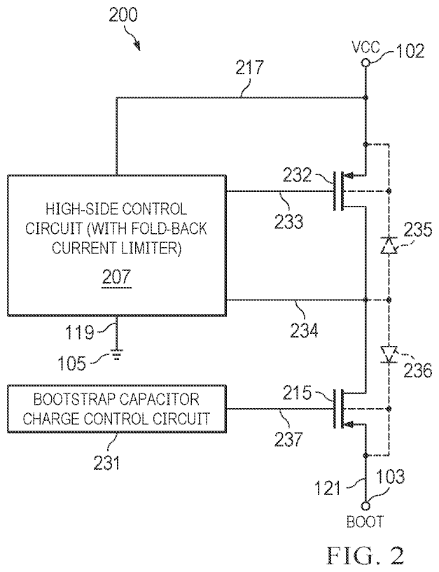

FIG. 2 is a block diagram illustrating a circuit with a high-side control circuit and a bootstrap capacitor charge control circuit in accordance with some aspects of the present disclosure. Circuit 200 comprises regulated voltage terminal 102, high-side control circuit 207, bootstrap capacitor charge control circuit 231, current-limiting transistor 232, bootstrap capacitor charge control transistor 215, and bootstrap capacitor terminal 103. Regulated voltage terminal 102 is coupled to connection structure 217, which is coupled to high-side control circuit 207 and to the source terminal of current-limiting transistor 232. High-side control circuit 207 is coupled to ground connection structure 119, which is coupled to ground terminal 105.

High-side control circuit 207 provides a current-limiting control signal on connection structure 233 to a gate terminal of current-limiting transistor 232. A drain terminal of current-limiting transistor 232 is coupled to a drain terminal of bootstrap capacitor charge control transistor 215 and to a connection structure 234, which is coupled to high-side control circuit 207.

Bootstrap capacitor charge control circuit 231 is coupled to bootstrap capacitor charge control transistor gate connection structure 237, which is coupled to a gate terminal of bootstrap capacitor charge control transistor 215. A source terminal of bootstrap capacitor charge control transistor 215 is coupled to bootstrap capacitor connection structure 121, which is coupled to bootstrap capacitor terminal 103.

Also depicted in FIG. 2 are current-limiting transistor body diode 235 of current-limiting transistor 232 and bootstrap capacitor charge control transistor body diode 236 of bootstrap capacitor charge control transistor 215. A cathode terminal of current-limiting transistor body diode 235 is coupled to a body terminal of current-limiting transistor 232 and to a source terminal of current-limiting transistor 232. An anode terminal of current-limiting transistor body diode 235 is coupled to connection structure 234. An anode terminal of bootstrap capacitor charge control transistor body diode 236 is coupled to connection structure 234. A cathode terminal of bootstrap capacitor charge control transistor body diode 236 is coupled to bootstrap capacitor connection structure 121. As shown, the orientations of current-limiting transistor body diode 235 and bootstrap capacitor charge control transistor body diode 236 can be arranged to be opposite one another, blocking flow of current uncontrolled by current-limiting transistor 232 and bootstrap capacitor charge control transistor 215.

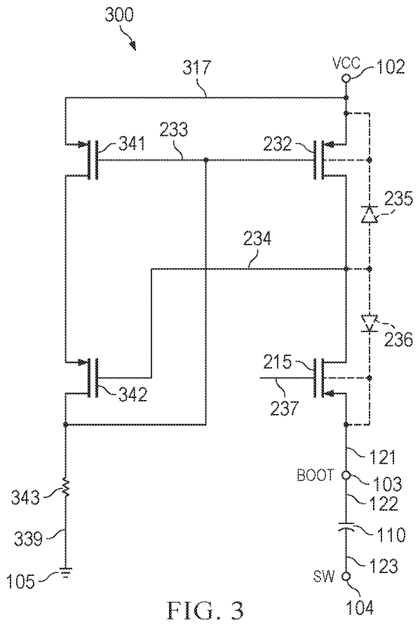

FIG. 3 is a schematic diagram illustrating a high-side control circuit in accordance with some aspects of the present disclosure. Circuit 300 comprises regulated voltage terminal 102, first transistor 342, current-limiting transistor 232 as a second transistor, third transistor 341, resistor 343, bootstrap capacitor charge control transistor 215, and bootstrap capacitor terminal 103. In accordance with some aspects, first transistor 342, current-limiting transistor 232, third transistor 341, and bootstrap capacitor charge control transistor 215 can be implemented as field-effect transistors (FETs), for example, P-channel FETs (PFETs). A first terminal 122 of bootstrap capacitor 110 can be coupled to bootstrap capacitor terminal 103. A second terminal 123 of bootstrap capacitor 110 can be coupled to switched terminal 104.

Regulated voltage terminal 102 is coupled to regulated voltage connection structure 317, which is coupled to a source terminal of third transistor 341 and to a source terminal of current-limiting transistor 232. A drain terminal of third transistor 341 is coupled to a source terminal of first transistor 342. A drain terminal of first transistor 342 is coupled to a first terminal of resistor 343, to a gate terminal of current-limiting transistor 232, and to a gate of third transistor 341 via connection structure 233. A second terminal of resistor 343 is coupled to ground connection structure 339, which is coupled to ground terminal 105.

A drain terminal of current-limiting transistor 232 is coupled to a gate terminal of first transistor 342 and to a drain terminal of bootstrap capacitor charge control transistor 215 via connection structure 234. Bootstrap capacitor charge control transistor gate connection structure 237 is coupled to a gate of bootstrap capacitor charge control transistor 215. A source of bootstrap capacitor charge control transistor is coupled to bootstrap capacitor connection structure 121, which is coupled to bootstrap capacitor terminal 103. Current-limiting transistor body diode 235 of current-limiting transistor 232 and bootstrap capacitor charge control transistor body diode 236 of bootstrap capacitor charge control transistor 215 are illustrated as previously described.

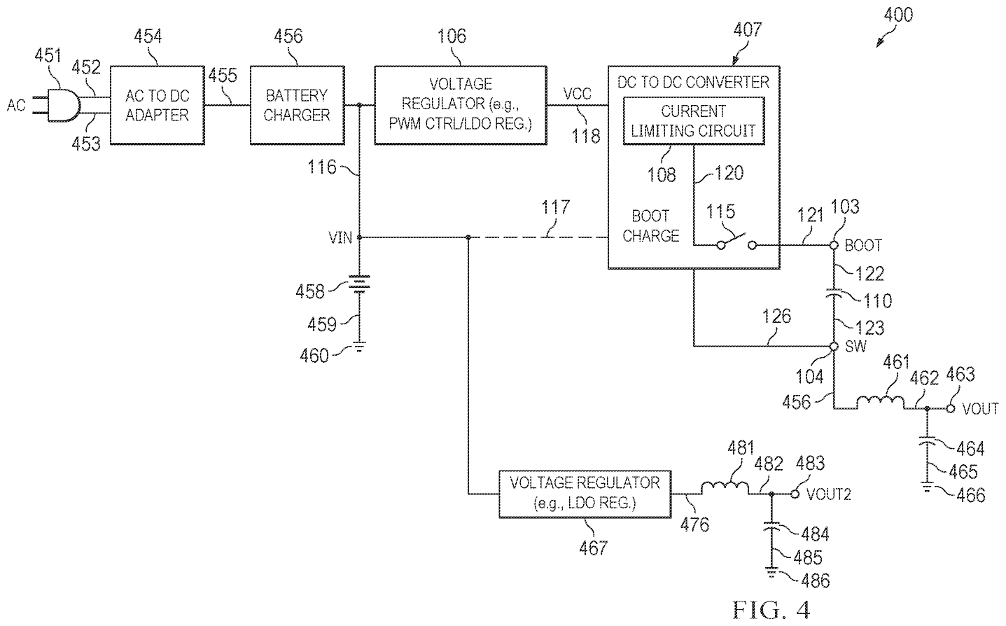

FIG. 4 is a block diagram illustrating a system comprising a DC-to-DC converter comprising a current limiting circuit in accordance with some aspects of the present disclosure. System 400 comprises alternating current (AC) power plug 451, AC to DC adapter 454, battery charger 456, battery 458, voltage regulator 106, DC-to-DC converter 407, bootstrap capacitor terminal 103, bootstrap capacitor 110, switched terminal 104, inductor 461, capacitor 464, output voltage terminal (VOUT) 463, voltage regulator 467, second inductor 481, second capacitor 484, and second output voltage terminal (VOUT2) 483. AC power plug 451 is coupled to AC power connection structures 452 and 453, which are coupled to an input of AC to DC adapter 454. An output of AC to DC adapter 454 is coupled to connection structure 455, which is coupled to an input of battery charger 456. An output of battery charger 456 is coupled to input voltage connection structure 116, which is coupled to an input of voltage regulator 106, to a first terminal of battery 458, and to an input of voltage regulator 467. In some embodiments, a connection structure may connect input voltage connection structure 116 to an input of DC-to-DC converter 407. A second terminal of battery 458 is coupled to ground connection structure 459, which is coupled to ground terminal 460.

An output of voltage regulator 106 is coupled to regulated voltage connection structure 118, which is coupled to an input of DC-to-DC converter 407. DC-to-DC converter 407 comprises current limiting circuit 108 and bootstrap capacitor charging circuit 109. An output of current limiting circuit 108 is coupled to bootstrap capacitor charging connection structure 120, which is coupled to a first terminal of switch 115 of bootstrap capacitor charging circuit 109. A second terminal of bootstrap capacitor charging circuit 109 is coupled to bootstrap capacitor charging connection structure, which is coupled to bootstrap capacitor terminal 103. An output of DC-to-DC converter 407 is coupled to switched connection structure 126, which is coupled to switched terminal 104. Switched terminal 104 is coupled to inductor connection structure 468, which is coupled to a first terminal of inductor 461. A second terminal of inductor 461 is coupled to output voltage connection structure 462, which is coupled to output voltage (VOUT) terminal 463 and to a first terminal of capacitor 464. A second terminal of capacitor 464 is coupled to ground connection structure 465, which is coupled to ground terminal 466.

An output of voltage regulator 467 is coupled to inductor connection structure 476, which is coupled to a first terminal of second inductor 481. A second terminal of second inductor 481 is coupled to second output voltage connection structure 482, which is coupled to second output voltage (VOUT2) terminal 483 and to a first terminal of second capacitor 484. A second terminal of second capacitor 484 is coupled to ground connection structure 485, which is coupled to ground terminal 486.

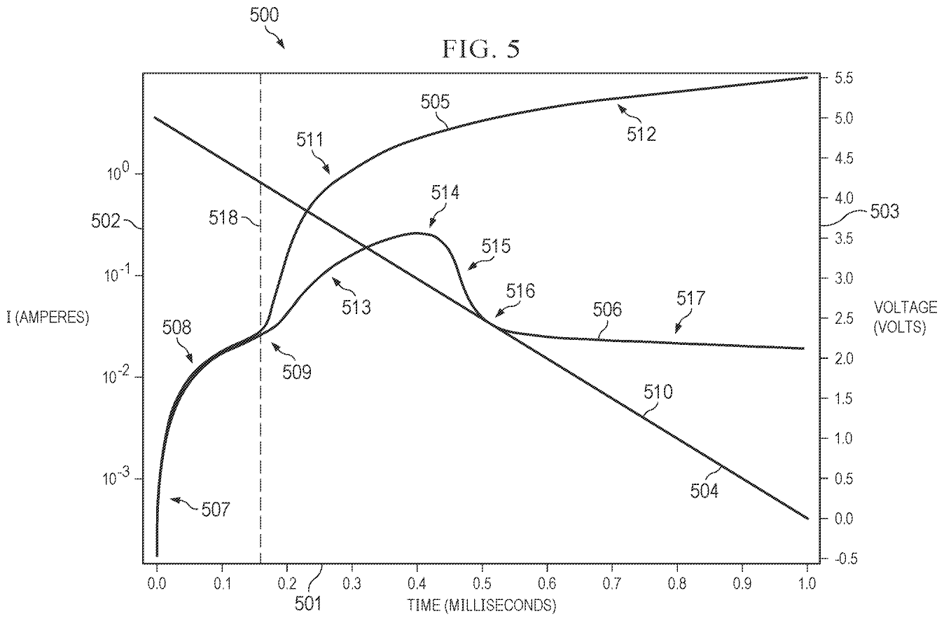

FIG. 5 is a graph showing voltage vs. time and current vs. time for an unprotected bootstrap charging circuit and for a current-limited bootstrap charging circuit in accordance with some aspects of the present disclosure. Graph 500 plots voltage 504 over time axis 501 with respect to voltage axis 503. Voltage 504 declines linearly along line 510 over voltage axis 503 and over time values of time axis 501. Graph 500 plots unprotected bootstrap capacitor charging current 505 over time axis 501 with respect to current axis 502. Graph 500 plots current-limited bootstrap capacitor charging current 506 over time axis 501 with respect to current axis 502. Both unprotected bootstrap capacitor charging current 505 and current-limited bootstrap capacitor charging current 506 rise rapidly during curve portion 507 and start to taper off the rise at curve portion 508. At time 518, from point 509, unprotected bootstrap capacitor charging current 505 begins to rise steeply over curve portion 511 and tapers off the rise over curve portion 512 to reach a high final value with respect to current axis 502, which is logarithmic.

At time 518, from point 509, current-limited bootstrap capacitor charging current 506 rises at a comparatively lower rate over curve portion 513, peaking at curve portion 514. From curve portion 514, current-limited bootstrap capacitor charging current 506 declines over curve portion 515 and transitions at curve portion 516 to a gradual decline over curve portion 517. The final value of current-limited bootstrap capacitor charging current 506 is very much smaller than the final value of unprotected bootstrap capacitor charging current 505, as plotted against the logarithmic values of current axis 502.

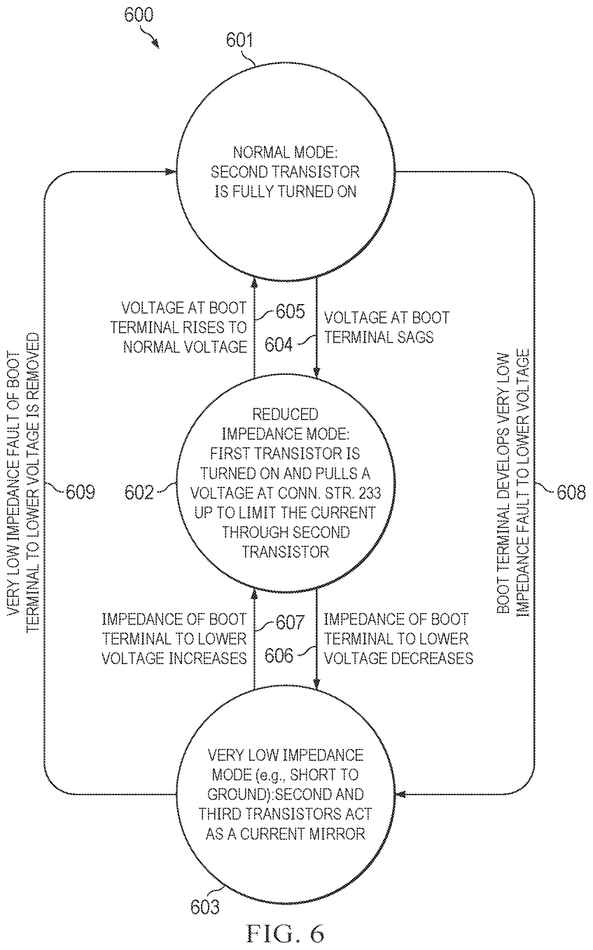

FIG. 6 is a state diagram illustrating states in which a current-limited bootstrap charging circuit can operate in accordance with some aspects of the present disclosure. State diagram 600 comprises a normal mode state 601, in which a current-limiting transistor, such as current-limiting transistor 232, is fully turned on. State diagram 600 comprises a reduced impedance mode state 602, in which a first transistor, such as first transistor 342, is turned on and pulls a voltage at a connection structure, such as connection structure 233, up to limit the current through the current-limiting transistor. State diagram 600 comprises a very low impedance mode state 603, in which a third transistor, such as third transistor 341, and the current-limiting transistor, such as current-limiting transistor 232, act as a current mirror. As an example, the very low impedance mode may occur if a bootstrap capacitor charging terminal were shorted to ground.

When a voltage at the bootstrap capacitor charging terminal sags, path 604 leads from normal mode state 601 to reduced impedance mode state 602. When the impedance of the bootstrap capacitor charging terminal to a lower voltage (e.g., ground) decreases, path 606 leads from reduced impedance mode state 602 to very low impedance mode state 603. When the impedance of the bootstrap capacitor charging terminal to the lower voltage increases, path 607 leads from very low impedance mode state 603 to reduced impedance mode state 602. When the voltage at the bootstrap capacitor charging terminal rises to a normal voltage, path 605 leads from reduced impedance mode state 602 to normal mode state 601. When the bootstrap capacitor charging terminal develops a very low impedance fault to a lower voltage, path 608 leads from normal mode state 601 to very low impedance mode state 603. When the very low impedance fault of the bootstrap charging terminal to the lower voltage is removed, path 609 leads from very low impedance mode state 603 to normal mode state 601.

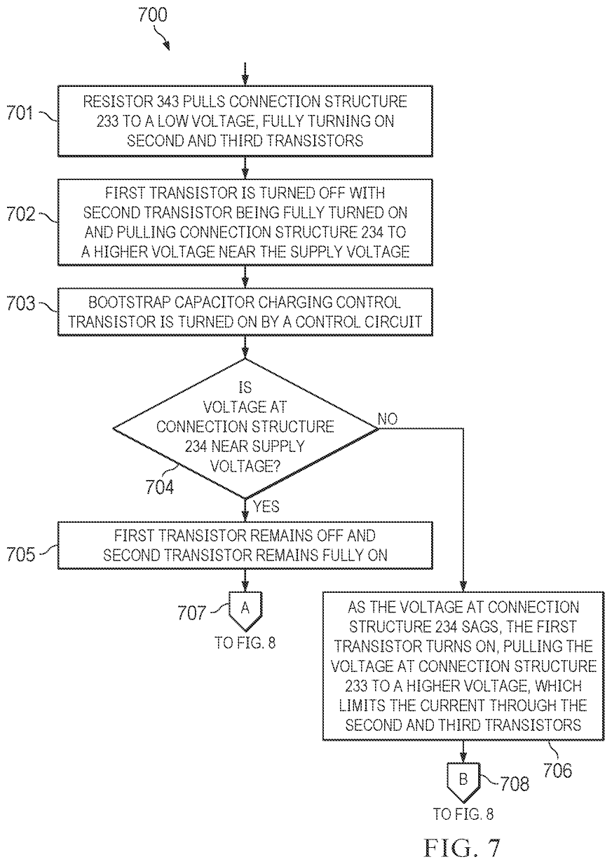

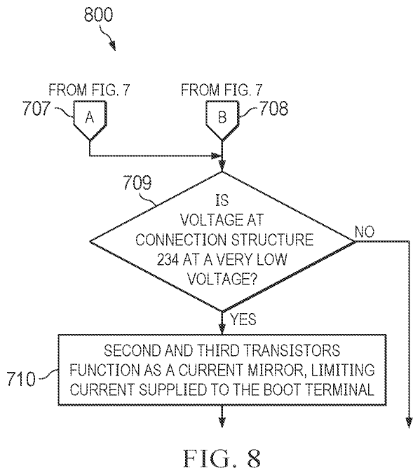

FIG. 7 and FIG. 8 are flow diagrams illustrating a method by which a current-limited bootstrap charging circuit may operate in accordance with some aspects of the present disclosure. The flow diagram spans flow diagram 700 of FIG. 7 and flow diagram 800 of FIG. 8. At block 701. a resistor, such as resistor 343, pulls a connection structure, such as connection structure 233, to a low voltage, fully turning on a current-limiting transistor, such as current-limiting transistor 232, and third transistor, such as third transistor 341. At block 702, A first transistor, such as first transistor 342, is turned off with the current-limiting transistor being fully turned on and pulling a connection structure, such as connection structure 234, to a higher voltage near a supply voltage. At block 703, a bootstrap capacitor charging control transistor, such a bootstrap capacitor charge control transistor 215, is turned on by a control circuit, such as bootstrap capacitor charge control circuit 231.

At decision block 704, a decision is made whether or not a voltage at the connection structure, such as connection structure 234, is near the supply voltage. If so, then at block 705 the first transistor remains off and the current-limiting transistor remains fully on. If not, then at block 706, as the voltage at the connection structure, such as connection structure 234, sags, the first transistor turns on, pulling the voltage at the connection structure, such as connection structure 233, to a higher voltage, which limits the current through the current-limiting transistor and the third transistor. In either case, following reference A 707 for the former case or reference B 708 for the latter case, at decision block 709, a decision is made whether the voltage at the connection structure, such as connection structure 234, is at a very low voltage. If so, at block 710, the current-limiting transistor and the third transistor function as a current mirror, limiting current supplied to the bootstrap capacitor charging terminal.

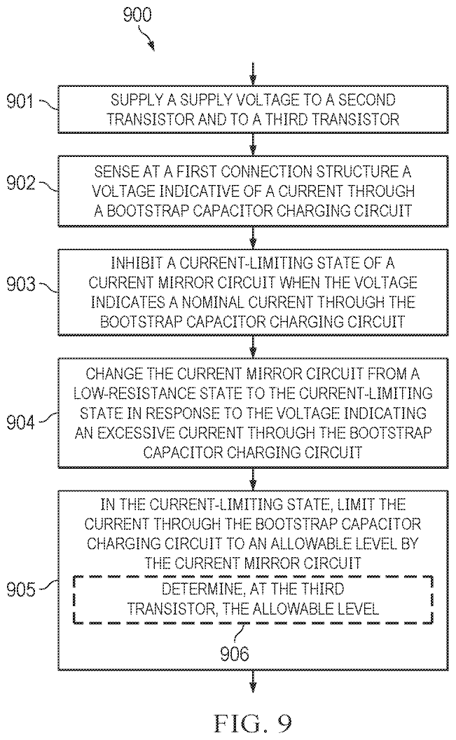

FIG. 9 is a flow diagram illustrating a method by which a current-limited bootstrap charging circuit may operate in accordance with some aspects of the present disclosure. On flow diagram 900, at block 901, a supply voltage is supplied to a second transistor (e.g., a current-limiting transistor) and to a third transistor. At block 902, a voltage indicative of a current through a bootstrap capacitor charging circuit is sensed at a connection structure, such as connection structure 233. At block 903, a current-limiting state of a current mirror circuit is inhibited when the voltage indicates a nominal current through the bootstrap capacitor charging circuit. At block 904, the current mirror circuit is changed from a low-resistance state to a current-limiting state in response to the voltage indicating an excessive current through the bootstrap capacitor charging circuit. At block 905, in the current-limiting state, the current through the bootstrap capacitor charging circuit is limited to an allowable level by the current mirror circuit. Block 905 can include block 906. At block 906, the allowable level is determined at the third transistor.

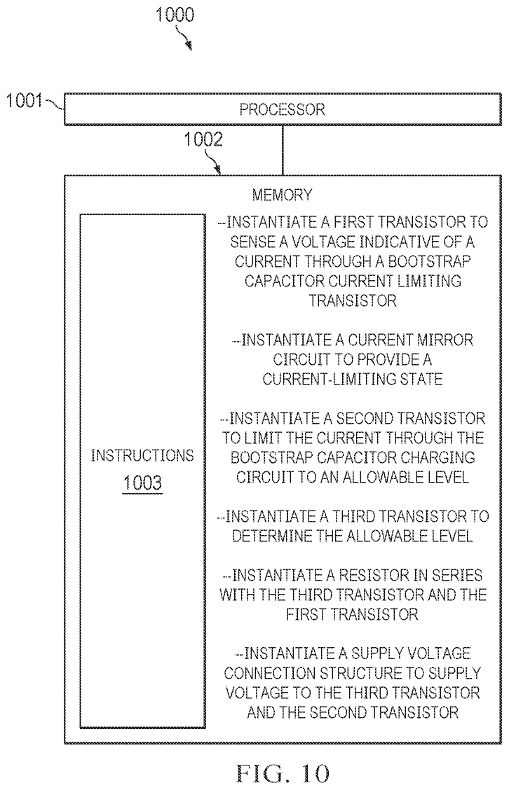

FIG. 10 is a block diagram illustrating apparatus comprising a processor and memory, the memory storing instructions executable by the processor in accordance with some aspects of the present disclosure. Apparatus 1000 comprises processor 1001 and memory 1002. Memory 1002 stores instructions 1003 which, when executed by processor 1001, cause the instantiation of a first transistor to sense a voltage indicative of a current through a bootstrap capacitor current limiting transistor, the instantiation of a current mirror circuit to provide a current-limiting state, the instantiation of a second transistor to limit the current through the bootstrap capacitor charging circuit to an allowable level, the instantiation of a third transistor to determine the allowable level, the instantiation of a resistor in series with the first transistor and the third transistor, and the instantiation of a supply voltage connection structure to supply voltage to the third transistor and the second transistor.

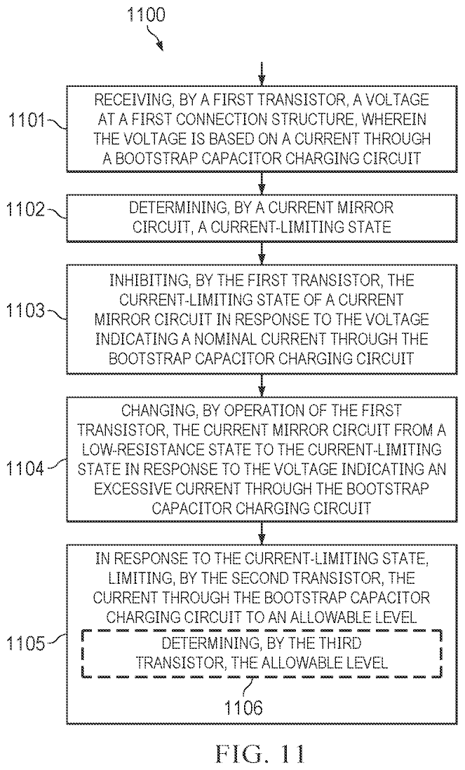

FIG. 11 is a flow diagram illustrating a method by which a current-limited bootstrap charging circuit may operate in accordance with some aspects of the present disclosure. On flow diagram 1100, at block 1101, a first transistor receives a voltage at a first connection structure, wherein the voltage is based on a current through a bootstrap capacitor charging circuit. At block 1102, a current mirror circuit determines a current-limiting state. Operation with respect to the current-limiting state can be more fully described in accordance with the examples set forth in blocks 1103 through 1106. At block 1103, the current-limiting state of the current mirror circuit is inhibited by the first transistor in response to the voltage indicating a nominal current through the bootstrap capacitor charging circuit. At block 1104, the current mirror circuit is changed, by operation of the first transistor, from a low-resistance state to the current-limiting state in response to the voltage indicating an excessive current through the bootstrap capacitor charging circuit. At block 1105, in response to the current-limiting state, the current through the bootstrap capacitor charging circuit is limited, by the second transistor, to an allowable level. Block 1105 can include block 1106. At block 1106, the allowable level is determined by the third transistor. In some aspects, the third transistor and the second transistor form the current mirror circuit.

In some aspects, a circuit, such as an integrated circuit, comprises a bootstrap capacitor terminal, a bootstrap capacitor charging circuit coupled to the bootstrap capacitor terminal; and a bootstrap capacitor charging current limiting circuit coupled to the bootstrap capacitor charging circuit. As an example, the bootstrap capacitor charging current limiting circuit can comprise a first transistor having a first gate terminal coupled to a first connection structure along a bootstrap capacitor charging current path, the first transistor having a first source terminal and a first drain terminal. As a further example, the bootstrap capacitor charging current limiting circuit can comprise a second transistor having a second gate terminal coupled to a second connection structure having a second connection structure voltage controlled by the first transistor, the second transistor having a second source terminal and a second drain terminal, the second source terminal and the second drain terminal coupled in the bootstrap capacitor charging current path. As a further example, the bootstrap capacitor charging current limiting circuit can comprise a third transistor having a third gate terminal coupled to the second connection structure, the third transistor having a third source terminal and a third drain terminal, the third source terminal, the third drain terminal, the first source terminal, and the first drain terminal coupled to put the third transistor and the first transistor in series between a supply voltage connection structure and the second connection structure. As a further example, the second transistor and the third transistor form a current mirror controlled by the first transistor. As another example, the second transistor is coupled to the supply voltage connection structure. As another example, the circuit comprises a resistor, wherein a first resistor terminal of the resistor is coupled to first transistor and a second resistor terminal of the resistor is coupled to a fixed voltage connection structure.

In some aspects, the circuit comprises a capacitor terminal, a capacitor charging transistor coupled to the capacitor terminal, a capacitor charging current sensing transistor coupled to the capacitor charging transistor, a current programming transistor coupled to the capacitor charging current sensing transistor; and a capacitor current limiting transistor coupled to the capacitor charging current sensing transistor, to the current programming transistor, and to the capacitor charging transistor. As an example, the circuit comprises a resistor coupled to the capacitor current limiting transistor, the resistor further coupled to the capacitor charging current sensing transistor, and the resistor further coupled to the current programming transistor. As a further example, a first resistor terminal of the resistor is coupled to a capacitor charging current sensing transistor drain terminal of the capacitor charging current sensing transistor, to a capacitor current limiting transistor gate terminal of the capacitor current limiting transistor, and to a current programming transistor gate terminal of the current programming transistor, and wherein a second resistor terminal of the resistor is coupled to a fixed voltage connection structure. As a further example, a capacitor charging current sensing transistor source terminal of the capacitor charging current sensing transistor is coupled to a current programming transistor drain terminal of the current programming transistor. As a further example, the capacitor terminal is coupled to a capacitor charging transistor source terminal of the capacitor charging transistor, wherein a capacitor charging transistor drain terminal of the capacitor charging transistor is coupled to a capacitor current limiting transistor source terminal of the capacitor current limiting transistor and to the capacitor charging current sensing transistor gate terminal of the capacitor charging current sensing transistor. As a further example, a current programming transistor source terminal of the current programming transistor and a capacitor current limiting transistor source terminal of the capacitor current limiting transistor are coupled to a supply voltage connection structure. As a further example, the current programming transistor and the capacitor current limiting transistor are coupled as a current mirror.

According to some aspects, an apparatus comprises a memory storing instructions to cause a processor to instantiate bootstrap capacitor charging current limiting circuit features. As an example, an apparatus comprises a processor and a memory, the memory storing instructions, the instructions, when executed by the processor, causing the processor to instantiate a first transistor, the first transistor configured to sense, at a first connection structure, a voltage indicative of a current through a bootstrap capacitor charging circuit, and instantiate a current mirror circuit, the current mirror circuit configured to provide a current-limiting state, the current-limiting state of the current mirror circuit configured to be inhibited by the first transistor when the voltage indicates a nominal current through the bootstrap capacitor charging circuit, the current mirror circuit being configured to change, by operation of the first transistor, from a low-resistance state to the current-limiting state in response to the voltage indicating an excessive current through the bootstrap capacitor charging circuit. As an example, the instructions can cause the processor to instantiate a second transistor, the second transistor configured to, in the current-limiting state, limit, the current through the bootstrap capacitor charging circuit to an allowable level. As a further example, the instructions can cause the processor to instantiate a third transistor, the third transistor configured to determine the allowable level. As a further example, the third transistor and the second transistor form the current mirror circuit. As a further example, the instructions can cause the processor to instantiate a resistor in series with the third transistor and the first transistor, wherein the allowable level depends on a resistance of the resistor. As a further example, the instructions can cause the processor to instantiate a supply voltage connection structure, the supply voltage connection structure configured to supply a supply voltage to the third transistor and the second transistor. As an example, the instructions may be stored on a non-transitory computer-readable medium. As an example, the instructions may be loaded from the non-transitory computer-readable medium for execution by the processor.

According to some aspects, a method comprises receiving, by a first transistor, a voltage at a first connection structure, wherein the voltage is based on a current through a bootstrap capacitor charging circuit and determining, by a current mirror circuit, a current-limiting state, wherein, in response to the voltage indicating a nominal current through the bootstrap capacitor charging circuit, the current-limiting state of the current mirror circuit is configured to be inhibited by the first transistor and, in response to the voltage indicating an excessive current through the bootstrap capacitor charging circuit, the current mirror circuit is configured to change, by operation of the first transistor, from a low-resistance state to the current-limiting state, As an example, the method may further comprise, in response to the current-limiting state, limiting, by a second transistor, the current through the bootstrap capacitor charging circuit to an allowable level. As an example, the method may further comprise determining, by a third transistor, the allowable level. As an example, the third transistor and the second transistor may form the current mirror circuit. As an example, the allowable level may depend on a resistance of a resistor in series with the third transistor and the first transistor. As an example, the third transistor and the second transistor may be coupled to a supply voltage.

The methods are illustrated and described above as a series of operations or events, but the illustrated ordering of such operations or events is not limiting. For example, some operations or events may occur in different orders and/or concurrently with other operations or events apart from those illustrated and/or described herein. Also, some illustrated operations or events are optional to implement one or more aspects or examples of this description. Further, one or more of the operations or events depicted herein may be performed in one or more separate operations and/or phases. In some examples, the methods described above may be implemented in a computer readable medium using instructions stored in a memory.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

The term “on” as used herein in reference to a transistor refers to a transistor in the Ohmic region of operation, conducting current in a forward direction with little resistance between the source and drain. The term “off” as used herein in reference to a transistor refers to a transistor in a state such that there is approximately no forward current conduction between the drain and source.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors are described herein, other transistors (or equivalent devices) may be used instead with little or no change to the remaining circuitry. For example, a field effect transistor, a bipolar junction transistor (BJT—e.g., NPN or PNP), insulated gate bipolar transistors (IGBTs), and/or junction field effect transistor (JFET) may be used in place of or in conjunction with the devices described herein. The transistors may be depletion mode devices, drain-extended devices, enhancement mode devices, natural transistors or other type of device structure transistors. Furthermore, the devices may be implemented in/over a silicon substrate (Si), a silicon carbide substrate (SiC), a gallium nitride substrate (GaN) or a gallium arsenide substrate (GaAs).

While certain elements of the described examples are included in an integrated circuit and other elements are external to the integrated circuit, in other examples, additional or fewer features may be incorporated into the integrated circuit. Also, some or all of the features illustrated as being external to the integrated circuit may be included in the integrated circuit and/or some features illustrated as being internal to the integrated circuit may be incorporated outside of the integrated circuit. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. As used herein, the term “ground” may exemplify a fixed voltage, such that a ground terminal may exemplify a fixed voltage terminal and a ground connection structure may exemplify a fixed voltage connection structure. Unless otherwise stated, “about,” “approximately,” or “substantially” preceding a value means +/−10 percent of that parameter. Modifications are possible in the described examples, and other implementations are possible, within the scope of the claims.

What is claimed is:

1. An integrated circuit comprising:
a bootstrap capacitor terminal;
a bootstrap capacitor charging circuit coupled to the bootstrap capacitor terminal; and
a bootstrap capacitor charging current limiting circuit coupled to the bootstrap capacitor charging circuit.

2. The integrated circuit of claim 1, wherein the bootstrap capacitor charging current limiting circuit comprises:
a first transistor having a first gate terminal coupled to a first connection structure along a bootstrap capacitor charging current path, the first transistor having a first source terminal and a first drain terminal.

3. The integrated circuit of claim 2, wherein the bootstrap capacitor charging current limiting circuit further comprises:
a second transistor having a second gate terminal coupled to a second connection structure having a second connection structure voltage controlled by the first transistor, the second transistor having a second source terminal and a second drain terminal, the second source terminal and the second drain terminal coupled in the bootstrap capacitor charging current path.

4. The integrated circuit of claim 3, wherein the bootstrap capacitor charging current limiting circuit further comprises:
a third transistor having a third gate terminal coupled to the second connection structure, the third transistor having a third source terminal and a third drain terminal, the third source terminal, the third drain terminal, the first source terminal, and the first drain terminal coupled to put the third transistor and the first transistor in series between a supply voltage connection structure and the second connection structure.

5. The integrated circuit of claim 4 wherein the second transistor and the third transistor form a current mirror controlled by the first transistor.

6. The integrated circuit of claim 4, wherein the second transistor is coupled to the supply voltage connection structure.

7. The integrated circuit of claim 4 further comprising:
a resistor, wherein a first resistor terminal of the resistor is coupled to first transistor and a second resistor terminal of the resistor is coupled to a fixed voltage connection structure.

8. A circuit comprising:
a capacitor terminal;
a capacitor charging transistor coupled to the capacitor terminal;
a capacitor charging current sensing transistor coupled to the capacitor charging transistor;
a current programming transistor coupled to the capacitor charging current sensing transistor; and
a capacitor current limiting transistor coupled to the capacitor charging current sensing transistor, to the current programming transistor, and to the capacitor charging transistor.

9. The circuit of claim 8 further comprising:
a resistor coupled to the capacitor current limiting transistor, the resistor further coupled to the capacitor charging current sensing transistor, and the resistor further coupled to the current programming transistor.

10. The circuit of claim 9, wherein a first resistor terminal of the resistor is coupled to a capacitor charging current sensing transistor drain terminal of the capacitor charging current sensing transistor, to a capacitor current limiting transistor gate terminal of the capacitor current limiting transistor, and to a current programming transistor gate terminal of the current programming transistor, and wherein a second resistor terminal of the resistor is coupled to a fixed voltage connection structure.

11. The circuit of claim 10, wherein a capacitor charging current sensing transistor source terminal of the capacitor charging current sensing transistor is coupled to a current programming transistor drain terminal of the current programming transistor.

12. The circuit of claim 11, wherein the capacitor terminal is coupled to a capacitor charging transistor source terminal of the capacitor charging transistor, wherein a capacitor charging transistor drain terminal of the capacitor charging transistor is coupled to a capacitor current limiting transistor source terminal of the capacitor current limiting transistor and to the capacitor charging current sensing transistor gate terminal of the capacitor charging current sensing transistor.

13. The circuit of claim 12, wherein a current programming transistor source terminal of the current programming transistor and a capacitor current limiting transistor source terminal of the capacitor current limiting transistor are coupled to a supply voltage connection structure.

14. The circuit of claim 13, wherein the current programming transistor and the capacitor current limiting transistor are coupled as a current mirror.

15. A method comprising:
receiving, by a first transistor, a voltage at a first connection structure, wherein the voltage is based on a current through a bootstrap capacitor charging circuit; and
determining, by a current mirror circuit, a current-limiting state, wherein:
in response to the voltage indicating a nominal current through the bootstrap capacitor charging circuit, the current-limiting state of the current mirror circuit is configured to be inhibited by the first transistor; and
in response to the voltage indicating an excessive current through the bootstrap capacitor charging circuit, the current mirror circuit is configured to change, by operation of the first transistor, from a low-resistance state to the current-limiting state.

16. The method of claim 15, further comprising:
in response to the current-limiting state, limiting, by a second transistor, the current through the bootstrap capacitor charging circuit to an allowable level.

17. The method of claim 16, further comprising:
determining, by a third transistor, the allowable level.

18. The method of claim 17, wherein the third transistor and the second transistor form the current mirror circuit.

19. The method of claim 18, wherein the allowable level depends on a resistance of a resistor in series with the third transistor and the first transistor.

20. The method of claim 19, wherein the third transistor and the second transistor are coupled to a supply voltage.
